(19) United States
(12) Patent Application Publication
(10) Pub. No.: US 2024/0421176 A1
(43) Pub. Date: Dec. 19, 2024

(54) OPTICAL PACKAGE COMPRISING A CAP AND A SUPPORT SUBSTRATE CONNECTED TOGETHER

(71) Applicant: STMicroelectronics International N.V., Geneve (CH)

(72) Inventors: Florian Perminjat, Saint Romans (FR); Vincent Beix, Chambéry (FR); Yandong Mao, Shanghai (CN); Karine Saxod, Porte De Savoie (FR)

(21) Appl. No.: 18/734,573

(22) Filed: Jun. 5, 2024

(30) Foreign Application Priority Data
Jun. 14, 2023 (FR) 2306056

(51) Int. Cl. H01L 27/146

(52) U.S. Cl. CPC H01L 27/14636; H01L 27/14618; H01L 27/14683

(57) ABSTRACT

An optical package comprising a support substrate including first electrical contacts, a cap fixed to the support substrate by adhesive and comprising second electrical contacts connected to the first electrical contacts by a soldering material, a separation structure disposed between the soldering material and the adhesive

### CROSS-REFERENCE TO RELATED APPLICATIONS

This application claims priority to French Patent Application No. FR 2306056, filed on Jun. 14, 2023, which application is hereby incorporated herein by reference.

### TECHNICAL FIELD

Embodiments and implementations relate to the field of electronics, in particular the field of integrated circuit packaging and more particularly the connection between a cap (or cover) and a support substrate of an optical package.

### BACKGROUND

An optical package typically provides an electrical connection between the cap and the support substrate so as to detect a failure of the optical elements of the cap and to control, for example, a cut-off of the power supply within the optical package. In particular, the supply of power to the electronic chips of the package can be cut-off so as to prevent the emission of optical radiation through these faulty optical elements.

This electrical connection is established by soldering between electrical contacts of the cap and substrate, carried out during the assembly of the cap on the support substrate. The cap is usually attached to the substrate using an adhesive. However, the soldering material and the adhesive can come into contact and mix when assembling the cap, producing electrical malfunctions such as short circuits, for example.

In this respect, the soldering material can be deposited sufficiently far from the adhesive to avoid mixing. This type of conventional deposition is restrictive because it can require a larger substrate surface area.

There is therefore an advantage to enable the electrical connection of the cap to the substrate without producing an electrical malfunction, whilst limiting the surface set aside for this electrical connection.

### SUMMARY

According to one aspect, an optical package is provided comprising a support substrate including first electrical contacts, a cap fixed to the support substrate by adhesive and comprising second electrical contacts connected to the first electrical contacts by a soldering material, wherein assembly means are designed to provide a separation between the soldering material and the adhesive.

More particularly, the assembly means make it possible to provide a separation that can be a separation by distance, which is thus intended to prevent the soldering material and the adhesive from mixing together, or a separation obtained due to the nature of the adhesive preventing such mixing even if the soldering material comes into contact with the adhesive.

The first contacts and the second contacts can thus be soldered by the soldering material with a limited surface footprint on the surface of the support substrate and without the risk of the soldering material and adhesive mixing.

According to one embodiment, the assembly means include an arrangement in the second electrical contacts designed to house part of the soldering material.

In this embodiment, the arrangement is a structural modification of the cap to allow excess soldering material to be removed in order to prevent contact between the soldering material and the adhesive. A cap comprising such an arrangement is designed in particular to be electrically connected to a conventional support substrate.

According to one embodiment, the arrangement in the second contacts includes a first through hole having a closed contour on the inside of the second contacts, or an open contour on the outside of the second contacts, forming a passage allowing part of the soldering material to overflow outside of the cap or allowing injection of the soldering material through the first hole.

The first hole located in the second contacts of the cap allows the soldering material to be introduced after fixing the cap to the substrate with the adhesive, and also to remove the excess material.

According to one embodiment, the assembly means comprise an arrangement in the substrate designed to accommodate part of the soldering material.

In this embodiment, the arrangement is a structural modification of the support substrate making it possible to direct and accommodate the excess soldering material away from the adhesive. A support substrate comprising such an arrangement is designed in particular to enable an electrical connection of a conventional cap to this substrate.

According to one embodiment, the arrangement in the support substrate includes a first trench and a second trench around the first contacts, the first trench accommodating the adhesive and the second trench accommodating at least part of the soldering material.

The first trench accommodates the excess adhesive and the second trench accommodates the excess soldering material. In this way, the adhesive and the soldering material are kept away from each other so as to prevent them from mixing.

According to one embodiment, the arrangement in the support substrate includes a second through hole, allowing injection of the soldering material through the second hole.

The second hole allows the soldering process to be carried out independently of the fixing of the cap to the substrate during the manufacture of the optical package, thus allowing the adhesive to be polymerized before the soldering material is injected in order to avoid mixing the soldering material with the polymerized adhesive even if the soldering material is in contact with the adhesive.

According to one embodiment, the second contacts include a projection engaged in the second hole, facing the first contacts arranged on the sides of the second hole.

The projection improves the electrical connection between the second contacts of the cap and the first contacts of the support substrate, in a male-female type structure.

According to one embodiment, the assembly means include an arrangement in the cap and in the substrate capable of separating the first contacts and the second contacts by a distance, and capable of accommodating the soldering material including a solder wire or a solder bump.

In this embodiment, the arrangement is a structural modification of both the cap and the support substrate making it possible to establish an electrical connection between the cap and substrate using controlled connection means such as the solder wire or solder bump. Moreover, these connection means do not have the disadvantage of the risk of overflow and mixing with the adhesive.

According to another aspect, a method for assembling a support substrate is provided including first electrical contacts, with a cap comprising second contacts, comprising fixing the cap to the support substrate using adhesive, connecting the second contacts to the first electrical contacts using a soldering material, assembly means providing a separation between the soldering material and the adhesive during said fixing of the cap to the support substrate.

According to one embodiment, the assembly means include an arrangement formed in the second electrical contacts, part of the soldering material being housed in the arrangement during said assembly of the cap with the substrate.

According to one embodiment, the arrangement in the second contacts includes a first through hole having a closed contour on the inside or an open contour on the outside formed in the second contacts, part of the soldering material being housed in the first hole during said assembly.

According to one embodiment, said part of the soldering material is housed in the first hole, by an overflow of the soldering material outside the cap passing through the first hole.

According to one embodiment, said part of the soldering material is housed in the first hole, by injection of the soldering material through the first hole during said connection of the electrical contacts.

According to one embodiment, the assembly means include an arrangement formed in the substrate, part of the soldering material being housed in the arrangement during said assembly of the cap with the substrate.

According to one embodiment, the arrangement in the support substrate includes a first trench and a second trench formed in the support substrate around the first contacts, the adhesive being accommodated in the first trench and at least part of the soldering material being accommodated in the second trench, during said fixing of the cap.

According to one embodiment, the arrangement in the support substrate includes a second through hole formed in the support substrate, the method comprising injection of the soldering material through the second hole.

According to one embodiment, said fixing of the cap comprises engagement of a projection of the second contacts in the second hole facing the first contacts arranged on the sides of the second hole.

According to one embodiment, said step of connecting the second contacts to the first electrical contacts using a soldering material is carried out after polymerization of the adhesive fixing the cap to the support substrate.

According to one embodiment, the assembly means include an arrangement in the cap and in the substrate separating the first contacts and the second contacts by a distance, the method comprising forming the soldering material in the separation of said arrangement, by a solder wire or a solder bump.

### BRIEF DESCRIPTION OF THE DRAWINGS

Other advantages and features of the invention will become apparent upon examining the detailed description of non-limiting embodiments and implementations, and from the accompanying drawings, in which:

FIG. 1 schematically illustrates a sectional view of an optical package according to a first embodiment;

FIG. 2 schematically illustrates a top view of the support substrate of an optical package according to the first embodiment described with reference to FIG. 1;

FIG. 3 schematically illustrates a bottom view of a cap that can be fixed and connected to the support substrate as described with reference to FIGS. 1 and 2;

FIG. 4 schematically illustrates a bottom view of another cap, according to a second embodiment;

FIG. 5 schematically illustrates a bottom view of a cap, according to a third embodiment;

FIG. 6 schematically illustrates an oblique view of the cap as described with reference to FIG. 5;

FIG. 7 schematically illustrates a sectional view of the optical package according to a fourth embodiment;

FIG. 8 schematically illustrates a sectional view of the optical package according to a fifth embodiment;

FIG. 9 schematically illustrates a sectional view of an optical package according to a sixth embodiment;

FIG. 10 schematically illustrates a sectional view of an optical package according to a seventh embodiment;

FIG. 11 schematically illustrates the steps of an exemplary method for manufacturing the optical package described above with reference to FIGS. 1 and 2;

FIG. 12 schematically illustrates the steps of an exemplary method for manufacturing the optical packages described above with reference to FIGS. 7 and 8;

FIG. 13 schematically illustrates the steps of an exemplary method for manufacturing the optical packages described above with reference to FIGS. 4 and 5; and

FIG. 14 schematically illustrates the steps of an exemplary method for manufacturing the optical packages described above with reference to FIGS. 9 and 10.

### DETAILED DESCRIPTION OF ILLUSTRATIVE EMBODIMENTS

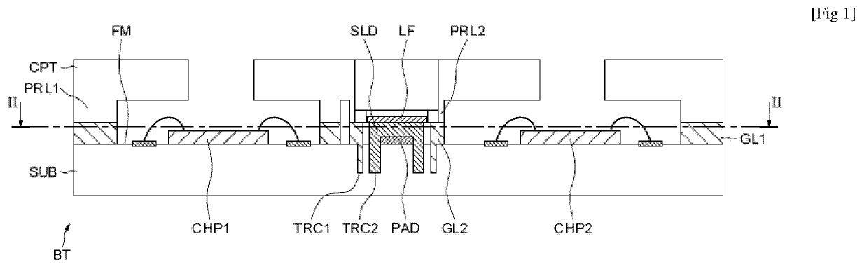

FIG. 1 schematically illustrates a sectional view of an optical package BT according to a first embodiment. The package BT includes a support substrate SUB comprising a mounting face FM, as well as a cap CPT comprising lateral walls PRL1 and PRL2 fixed to the mounting face FM of the support substrate SUB by adhesive GL1 and GL2. The adhesive GL1, GL2 can, for example, be epoxy glue. In particular, the lateral walls PRL1 and PRL2 delimit cavities that can house electronic chips CHP1 and CHP2, for example.

The electronic chips CHP1 and CHP2 are mounted and connected on the mounting face FM of the support substrate SUB in a “wire bonding” type assembly known to a person skilled in the art. In this type of package, the electronic chips CHP1 and CHP2 can be designed to emit or receive optical radiation passing, for example, through holes FNT1 and FNT2 of the cap CPT located opposite the electronic chips CHP1 and CHP2 on the optical path of the optical radiation.

Moreover, the optical package BT includes a metallic structure (usually known as a “lead frame”), which can be embedded in the cap CPT, for example, and makes it possible to electrically connect elements of the cap CPT, such as filters (not shown), to the support substrate SUB. The electrical connection between the cap CPT and the substrate SUB makes it possible to detect a cap CPT failure, such as filter delamination. The risk of the optical package BT malfunctioning caused by such a failure can thus be avoided, for example, by cutting off the power supply to the electronic chips CHP1 and/or CHP2 in the event that the failure is detected.

In order to establish this electrical connection between the cap CPT and the substrate SUB, the support substrate SUB includes first electrical contacts PAD and the cap CPT includes second electrical contacts LF connected to the first electrical contacts PAD by a soldering material SLD. The soldering material SLD can be metal in the form of solder paste that has been deposited on the first contacts PAD and on which the second contacts LF of the cap CPT rest.

However, the soldering material SLD may be incompatible with the adhesive Gl2, and it is desirable to prevent the soldering material SLD from mixing with the adhesive GL2.

In this regard, assembly means or separation structures are provided to allow the cap CPT to be electrically connected to the substrate SUB without a risk of malfunction and without the need for a larger surface set aside for the electrical connection and bonding of the cap CPT.

The assembly means or separation structure may take the form of structures of the support substrate SUB and/or of the cap CPT, hereinafter referred to as the “arrangement”, which can be produced in accordance with the various embodiments and implementations described with reference to FIGS. 1 to 14.

Indeed, the assembly means or separation structure are designed to provide a separation between the soldering material SLD and the adhesive GL2. The separation is, for example, a distance in the event that the soldering material SLD is kept away from the adhesive GL2. The separation can also be structural so as to prevent the soldering material SLD and the adhesive GL2 from mixing during the manufacturing process of the package BT, including if they come into contact.

In order to produce these separations, the separation structure include an arrangement in the support substrate SUB, as shown in FIGS. 1, 2, 7 and 8, or an arrangement in the support substrate SUB and the cap CPT, as shown in FIGS. 4-6, 9 and 10.

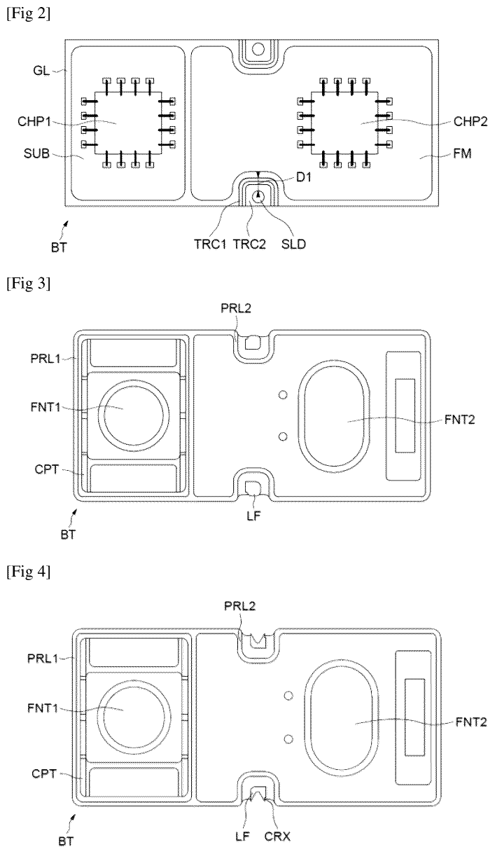

FIG. 2 schematically illustrates a top view of the support substrate SUB of an optical package BT according to the first embodiment described above with reference to FIG. 1, and more particularly an arrangement of the substrate SUB enabling a distance D1 to be maintained between the soldering material SLD and the adhesive GL2. The view in FIG. 2 is in plane II-II of FIG. 1.

The arrangement in the support substrate SUB includes a first trench TRC1 and a second trench TRC2 around the first contacts PAD. The first trench TRC1 accommodates the adhesive GL2, for example an excess of adhesive GL2 overflowing from the mounting face FM. The second trench TRC2 accommodates at least part of the soldering material SLD, for example an excess of soldering material SLD overflowing from the first electrical contacts PAD.

In this way, the package BT has a cap CPT, for example a conventional cap from the prior art having electrical contacts, connected to the support substrate SUB by the soldering material SLD kept away from the adhesive GL2 by the distance D1 by means of this arrangement.

The distance D1, which can be set depending on the excess quantity that can be deposited, and depending on the dimensions of the product and the available surface area on the substrate, is, for example, more than or equal to 200 μm.

FIG. 3 schematically illustrates a bottom view of a cap CPT that can be fixed and connected to the support substrate SUB as described above with reference to FIGS. 1 and 2. The lateral walls PRL1 and PRL2 of the cap CPT can in particular be fixed by the adhesive GL located on the contour of the substrate SUB and surround the electrical contacts LF of the cap CPT.

The cap CPT is intended to be assembled with the substrate SUB, and the walls PRL1, PRL2 are arranged in this respect to come into contact with the portion of the substrate intended to receive the layer of adhesive. In particular, the walls PRL2 are intended to be positioned opposite the trenches TRC1, and outside the contour of the trenches TRC2.

FIG. 4 schematically illustrates a bottom view of another cap CPT, according to a second embodiment. The elements in common with the cap CPT in FIG. 3 have the same references and will not all be detailed again.

In this second embodiment, an arrangement in the second electrical contacts LF is designed to house part of the soldering material SLD. This arrangement allows part of the soldering material SLD to overflow outside the cap CPT, and also allows the soldering material SLD to be introduced.

The arrangement in the second contacts LF includes a first through hole, which has an open contour on the outside CRX of the second contacts LF.

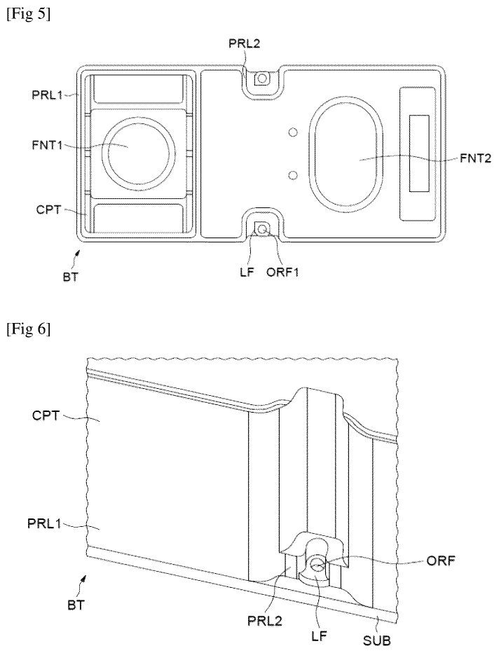

FIG. 5 schematically illustrates a bottom view of a cap CPT, according to a third embodiment. The elements in common with the cap CPT in FIG. 3 have the same references and will not all be detailed again.

In the second and third embodiment, the first through hole, the contour of which is closed or open, forms a passage allowing part of the soldering material SLD to overflow outside of the cap CPT or allowing injection of the soldering material through the first hole.

In addition, the first hole ORF1 located in the second contacts LF of the cap CPT constitutes a relatively simple means allowing the soldering material SLD to be introduced after the cap CPT has been fixed to the substrate SUB, in particular after the polymerization of the adhesive during chemical treatment, and/or the excess soldering material SLD to be removed.

FIG. 6 schematically illustrates an oblique view of the cap CPT as described above with reference to FIG. 5, enabling the assembled structure BT of the cap CPT and the substrate SUB to be distinguished.

In particular, the second contacts LF are surrounded by the lateral wall PRL2, which extends over a height of the cap whilst leaving a space, in the extension of the first hole, allowing an instrument to be put in place that is used to deposit the soldering material SLD.

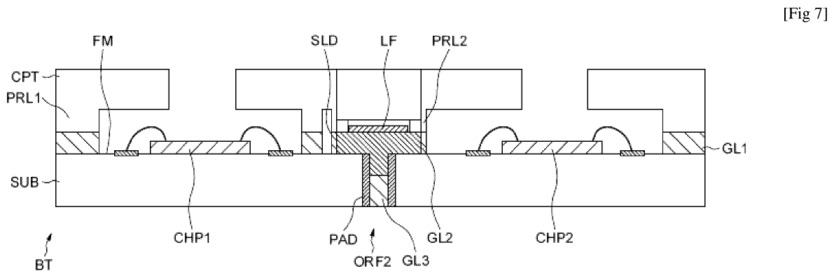

FIG. 7 schematically illustrates a sectional view of the optical package BT according to a fourth embodiment. The elements in common with the package BT in FIG. 1 have the same references and will not all be detailed again.

This fourth embodiment includes an arrangement in the substrate SUB including a second through hole ORF2, and allowing injection of the soldering material SLD through the second hole ORF2.

The second hole ORF2 can also be used to establish electrical connections with electronic components by means of electrical contacts arranged on the sides of the hole. Indeed, the first electrical contacts PAD of the substrate SUB are arranged on the sides of the second hole ORF2. It is thus possible to introduce the soldering material SLD into the second hole ORF2 during the process for manufacturing the package BT in order to make contact with the first electrical contacts PAD and the second electrical contacts LF of the cap CPT, after polymerization of the adhesive.

In addition, the second hole ORF2 can accommodate only the soldering material SLD or adhesive GL3 in addition to the soldering material SLD.

Thus, the soldering material SLD introduced after the cap CPT has been fixed can be in contact with the adhesive GL that has already been polymerized, for example when the excess soldering material SLD overflows onto the mounting face FM of the substrate SUB, without being mixed with the adhesive. As a consequence, this makes it possible to electrically connect the cap CPT to the substrate SUB without the risk of producing electrical malfunctions within the package BT.

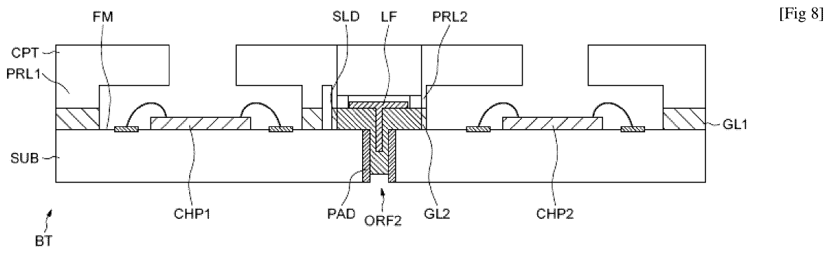

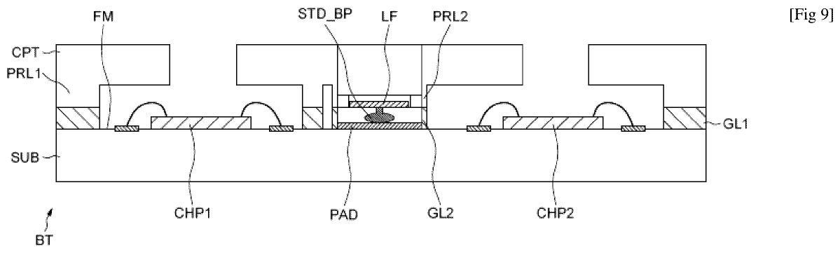

FIG. 8 schematically illustrates a sectional view of the optical package BT according to a fifth embodiment. The elements in common with the package BT in FIG. 1 have the same references and will not all be detailed again.

FIG. 8 illustrates a variant of the fourth embodiment described with reference to FIG. 7. In this variant, the second contacts LF include a projection engaged in the second hole ORF2, facing the first contacts PAD arranged on the sides of the second hole ORF2.

The projection improves the electrical connection between the second contacts LF of the cap CPT and the first contacts PAD of the support substrate SUB, in a male-female type structure.

FIG. 9 schematically illustrates a sectional view of an optical package BT according to a sixth embodiment. The elements in common with the package BT in FIG. 1 have the same references and will not all be detailed again.

The assembly means provided in this sixth embodiment include an arrangement in the cap CPT and in the support substrate SUB capable of separating the first contacts PAD and the second contacts LF by a distance. In addition, this arrangement is capable of accommodating a solder bump SLD_BP (usually referred to as a “stud bump”).

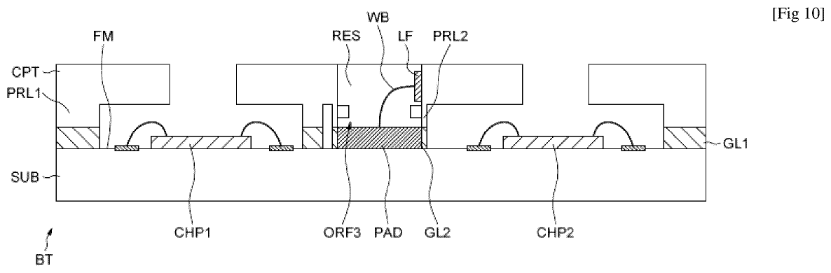

FIG. 10 schematically illustrates a sectional view of an optical package BT according to a seventh embodiment. The elements in common with the package BT in FIG. 1 have the same references and will not all be detailed again.

The arrangement is similar to that in the cap CPT and the substrate SUB of the package BT described above with reference to FIG. 9 and differs from it in that the second electrical contacts LF are arranged laterally on the lateral wall PRL2 of the cap CPT and in that the arrangement accommodates a solder wire WB. The solder wire WB is, for example, embedded in a glob top to protect it from the outside world.

Such an arrangement therefore enables an electrical connection to be established by a technique known as “wire bonding” frequently used to connect electronic chips. In particular, this electrical connection can be established after fixing the cap CPT, by passing the solder wire through a third hole ORF3 provided in the cap CPT opposite the first contacts PAD of the substrate SUB.

Consequently, the arrangement can comprise a simple structure providing a distance between the soldering material such as the solder bump SLD_BP or the solder wire WB and the adhesive. In addition, this can make it possible to establish an electrical connection between the first contacts PAD and the second contacts LF in a controlled manner, i.e. without the risk of the soldering material overflowing and mixing with the adhesive GL2 as it forms.

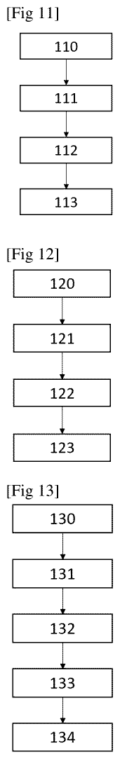

FIG. 11 schematically illustrates the steps of an exemplary method for manufacturing the optical package BT described above with reference to FIGS. 1 and 2.

The method comprises a step 110 of forming a support substrate SUB including first electrical contacts PAD.

The method comprises a step 111 of forming a first trench TRC1 and a second trench TRC2 around the first electrical contacts PAD.

The method comprises a step 112 of depositing a soldering material SLD and an adhesive GL on the substrate SUB. In particular, the soldering material SLD is deposited on the first electrical contacts PAD.

The method comprises a step 113 of fixing a cap CPT. In particular, a connection of the second contacts LF of the cap CPT to the first contacts PAD of the substrate SUB is established at the same time as the cap CPT is fixed. During this fixing operation, adhesive GL can overflow into the first trench TRC1 and at least part of the soldering material SLD can overflow into the second trench TRC2. In this way, the adhesive GL2 and the soldering material SLD remaining on the mounting face FM are separated by a distance D1 after the cap CPT has been fixed.

FIG. 12 schematically illustrates the steps of an exemplary method for manufacturing the optical packages BT described above with reference to FIGS. 7 and 8.

The method starts with step 120 corresponding to step 110 of forming the substrate SUB of the method described above with reference to FIG. 11.

The method comprises a step 121 of forming a second hole ORF2. The first electrical contacts PAD are formed on the sides of the second hole ORF2, for example by metallization on the sides of a hole using conventional techniques.

The method then comprises step 122 corresponding to step 113 of fixing the cap CPT of the method described above with reference to FIG. 11. After fixing the cap CPT, the adhesive GL can be polymerized during heat treatment of the optical package BT.

After the heat treatment, the method comprises a step 123 of injecting soldering material SLD through the second hole ORF2 such that the soldering material SLD passes through the second hole ORF2 and electrically connects the second contacts LF and the first contacts PAD. Adhesive GL3 or resin can also be injected to plug the second hole ORF2.

Alternatively, the cap CPT can comprise second contacts LF having a projection, in which case the step 122 of fixing the cap CPT is done so as to engage the projection of the second contacts LF in the second hole ORF2 facing the first contacts PAD, as shown in FIG. 8, before the injection 123 of the soldering material SLD.

The second hole ORF2 therefore enables an electrical connection to be established between the first contacts and the second contacts independently of the fixing of the cap CPT to the substrate SUB, thus allowing the adhesive to be polymerized before the soldering material is injected in order to avoid mixing the soldering material with the polymerized adhesive even if the soldering material is in contact with the adhesive.

FIG. 13 schematically illustrates the steps of an exemplary method for manufacturing the optical packages BT described above with reference to FIGS. 4 and 5.

The method comprises a step 130 of forming a cap CPT including second electrical contacts LF as well as a step 131 of forming a first through hole in the second electrical contacts LF. More particularly, the first hole has an open contour on the outside CRX or an open contour ORF1 formed in the second contacts LF.

The method comprises a step 132 of depositing an adhesive GL on a substrate SUB such as a conventional substrate and a step 133 of fixing the cap CPT in a similar way to steps 113 and 122 described above with reference to FIGS. 11 and 12. After fixing the cap CPT, the adhesive GL can be polymerized during heat treatment of the optical package BT.

After the heat treatment, the method comprises a step 134 of injecting soldering material SLD through the first hole such that the soldering material SLD passes through the first hole and electrically connects the second contacts LF and the first contacts PAD.

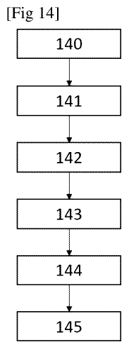

FIG. 14 schematically illustrates the steps of an exemplary method for manufacturing the optical packages BT described above with reference to FIGS. 9 and 10.

The method comprises a step 140 of forming the support substrate SUB and the cap CPT. The formation of the cap CPT can comprise the formation 141 of a third hole ORF3 and a formation 142 of the second electrical contacts LF on a lateral wall PRL2 of the cap CPT such that the second contacts are vertically oriented.

The method comprises, as an alternative to steps 141 and 142, a step 143 of forming a solder bump. Such a solder bump can be obtained by first depositing the soldering material SLD in the form of a ball on the first contacts PAD and, once the material is fixed to the first contacts, it is stretched and torn to form a point on which the second contacts LF can rest when the cap CPT is fixed.

The method then comprises a step 144 of fixing the cap CPT similar to steps 113, 122 and 133 described above with reference to FIGS. 11, 12, 13. In the case of the package BT shown in FIG. 9, the electrical connection between the first contacts PAD and the second contacts LF is established during the fixing step.

In the case of the package BT shown in FIG. 10, the first contacts PAD are connected to the second contacts LF using a wire bonding technique. Indeed, the method also includes a step 144 of forming a solder wire WB through the third hole ORF3 between the first contacts PAD and the second contacts LF as well as forming a glob top introduced through the third hole ORF3 so as to embed the solder wire WB.

What is claimed is:

1. An optical package comprising:
a support substrate including first electrical contacts;
a cap fixed to the support substrate by adhesive and comprising second electrical contacts connected to the first electrical contacts by a soldering material; and
a separation structure separating the soldering material from the adhesive.

2. The package according to claim 1, wherein the separation structure comprises an arrangement in the second electrical contacts housing a part of the soldering material.

3. The package according to claim 2, wherein the arrangement in the second contacts comprises a first through hole having a closed contour on the inside of the second contacts, or an open contour on the outside of the second contacts, forming a passage allowing part of the soldering material to overflow outside of the cap or allowing injection of the soldering material through the first hole.

4. The package according to claim 1, wherein the separation structure comprise an arrangement in the cap and in the substrate separating the first contacts and the second contacts by a distance, and accommodating the soldering material including a solder wire or a solder bump.

5. An optical package comprising:
a support substrate including first electrical contacts;
a cap fixed to the support substrate by adhesive and comprising second electrical contacts connected to the first electrical contacts by a soldering material; and
a separation structure separating the soldering material from the adhesive, wherein the separation structure comprises an arrangement in the substrate accommodating a part of the soldering material.

6. The package according to claim 5, wherein the arrangement in the support substrate comprises a first trench and a second trench around the first contacts, the first trench accommodating the adhesive and the second trench accommodating at least part of the soldering material.

7. The package according to claim 5, wherein the arrangement in the support substrate comprises a second through hole, allowing injection of the soldering material through the second hole.

8. The package according to claim 7, wherein the second contacts comprise a projection engaged in the second hole, facing the first contacts arranged on sides of the second hole.

9. A method comprising:
assembling a support substrate including first electrical contacts, with a cap comprising second electrical contacts, the assembling comprising
fixing the cap to the support substrate using adhesive,
connecting the second contacts to the first electrical contacts using a soldering material, a separation structure providing a separation between the soldering material and the adhesive during the fixing of the cap to the support substrate.

10. The method according to claim 9, wherein the separation structure comprise an arrangement formed in the second electrical contacts, part of the soldering material being housed in the arrangement during the assembly of the cap with the substrate.

11. The method according to claim 10, wherein the arrangement in the second contacts comprises a first through hole having a closed contour on the inside or an open contour on the outside formed in the second contacts, part of the soldering material being housed in the first hole during the assembly.

12. The method according to claim 11, wherein the part of the soldering material is housed in the first hole, by an overflow of the soldering material outside the cap passing through the first hole.

13. The method according to claim 11, wherein the part of the soldering material is housed in the first hole, by injection of the soldering material through the first hole during the connection of the electrical contacts.

14. The method according to claim 9, wherein the separation structure comprises an arrangement formed in the substrate, part of the soldering material being housed in the arrangement during the assembly of the cap with the substrate.

15. The method according to claim 14, wherein the arrangement in the support substrate comprises a first trench and a second trench formed in the support substrate around the first contacts, the adhesive being accommodated in the first trench and at least part of the soldering material being accommodated in the second trench, during the fixing of the cap.

16. The method according to claim 14, wherein the arrangement in the support substrate comprises a second through hole formed in the support substrate, the method comprising injection of the soldering material through the second through hole.

17. The method according to claim 14, wherein the fixing of the cap comprises engagement of a projection of the second electrical contacts in a second through hole facing the first contacts arranged on sides of the second through hole.

18. The method according to claim 9, wherein the connecting of the second contacts to the first electrical contacts using a soldering material is carried out after polymerization of the adhesive fixing the cap to the support substrate.

19. The method according to claim 9, wherein the separation structure include an arrangement in the cap and in the substrate separating the first contacts and the second contacts by a distance.

20. The method according to claim 9, further comprising forming the soldering material in the separation of the arrangement, by a solder wire or a solder bump.
